(19) United States
(12) Patent Application Publication
(10) Pub. No.: US 2023/0333222 A1
(43) Pub. Date: Oct. 19, 2023

(54) TOF OPTICAL SENSING MODULE

(71) Applicant: Egis Technology Inc., Hsinchu City (TW)

(72) Inventor: Tze-Sheng LIN, Hsinchu City (TW)

(21) Appl. No.: 18/147,623

(22) Filed: Dec. 28, 2022

Related U.S. Application Data
(60) Provisional application No. 63/332,280, filed on Apr. 19, 2022.

(30) Foreign Application Priority Data
Nov. 10, 2022 (CN) 2022114037947

(51) Int. Cl. G01S 7/486; G01S 17/10

(52) U.S. Cl. CPC G01S 7/4868; G01S 17/10

(57) ABSTRACT

A TOF optical sensing module includes a substrate, a cap, and a transceiving unit. The cap includes a body, and a transmitting window, a receiving window, a partition structure and at least one protruding structure all connected to the body. The body and the substrate define a chamber, and the protruding structure protrudes from the lower surface toward the chamber. The partition structure is disposed between the lower surface and the substrate to divide the chamber into an emitting chamber and a receiving chamber. The transceiving unit is configured to emit detection light and receive sensing light. Each of the protruding structures is disposed in the emitting chamber to reflect and/or absorb the detection light traveling in the emitting chamber towards the receiving chamber. Compared with the prior art, the TOF optical sensing module of the present disclosure has a higher accuracy in measuring the distance of a target object.

### CROSS-REFERENCE OF RELATED APPLICATION

An Application Data Sheet is filed concurrently with this specification as part of the present application. Each application that the present application claims benefit of or priority to as identified in the concurrently filed Application Data Sheet is incorporated by reference herein in its entirety and for all purposes.

### TECHNICAL FIELD

The present disclosure relates to a Time of Flight (TOF) optical sensing module.

### BACKGROUND

Today's smart phones, tablet computers or other handheld devices are equipped with optical modules to achieve gesture detecting, three-dimensional (3D) imaging, proximity detecting or camera focusing and other functions. The TOF sensor emits near infrared light toward the scene to measure the distance from the object in the scene according to the TOF information of light. The advantages of the TOF sensor include the small depth information calculation loading, the strong anti-interference and the long measurement range, so it has gradually been favored.

The core components of the TOF sensor include: a light source, more particularly an infrared vertical chamber surface emitting laser (VCSEL); an optical sensor, more particularly a single photon avalanche diode (SPAD); and a time-to-digital converter (TDC). The SPAD is a photoelectric detection avalanche diode having the single photon detection ability of generating a current as long as a weak optical signal is received. The VCSEL in the TOF sensor emits infrared pulse light to the scene, the SPAD receives the infrared pulse light reflected back from a target object, and the TDC records a time interval (i.e., a TOF) between the time of emitting and receiving the light, and calculates the distance of the to-be-measured object according to the TOF. Therefore, the accurate determination of the time interval between the time of emitting and receiving the light is directly related to the accuracy of the distance. In other words, it is necessary to accurately determine the time at which the VCSEL emits the infrared pulse light and the time at which the SPAD receives the infrared pulse light reflected back from the target object.

However, when the traditional TOF optical sensing module is used, a portion of the infrared pulse light emitted from the VCSEL is directly received by the SPAD in the interior of the TOF optical sensing module, and a time instant at which the portion of the infrared pulse light is received by the SPAD is earlier than another time instant at which another portion of the infrared pulse light is received by the SPAD after being reflected back from the to-be-measured object. Therefore, the former one of the two time instants will be wrongly used to calculate the distance of the to-be-measured object, resulting in an inaccurate result.

### SUMMARY

The present disclosure provides a TOF optical sensing module to solve the problem that it is difficult for the traditional TOF optical sensing module to accurately determine the distance of a to-be-measured object.

The embodiments of the present disclosure provide a TOF optical sensing module, including a substrate, a cap, and a transceiving unit. The cap includes a body, and a transmitting window, a receiving window, a partition structure and at least one protruding structure all connected to the body. The body and the substrate together define a chamber, the body has a lower surface facing the substrate and the chamber, and the protruding structure protrudes from the lower surface toward the chamber. The transceiving unit is provided in the chamber, and the partition structure is provided between the lower surface and the substrate to divide the chamber into an emitting chamber and a receiving chamber respectively corresponding to the transmitting window and the receiving window, in conjunction with the transceiving unit. The transceiving unit is configured to emit detection light from the emitting chamber and receive sensing light in the receiving chamber through the receiving window. Each of the protruding structures is disposed in the emitting chamber to reflect and/or absorb the detection light traveling in the emitting chamber towards the receiving chamber.

In the TOF optical sensing module of the present disclosure, the protruding structure in the emitting chamber increases the inner surface area of the emitting chamber, thus increasing the reflection and absorption amount and/or reflection and absorption times of stray light, and attenuating energy of the stray light, so as to reduce or prevent the stray light from entering the receiving chamber through the partition structure or the gap between the partition structure and the substrate. Therefore, as compared with the prior art, the TOF optical sensing module of the present disclosure has a higher accuracy in measuring the distance of the target object.

In addition, the protruding structure in the emitting chamber can also reduce the detection light reaching the reference pixel, thus avoiding the problem that the energy of the detection light received by the reference pixel of the traditional TOF optical sensing module is too high and additional processing is required to reduce the energy received by the reference pixel.

### BRIEF DESCRIPTION OF THE DRAWINGS

The drawings illustrated here provide a further understanding of the embodiments of the present disclosure, constitute a part of the specification to illustrate the embodiments of the present disclosure, and serve to explain the principle of the present disclosure together with the description. Obviously, the drawings described below involve only some embodiments of the present disclosure. For those of ordinary skill in the art, other drawings can be derived from these drawings without any inventive efforts. In the drawings:

FIGS. 1 and 2 illustrate structural schematic diagrams of a TOF optical sensing module according to an embodiment of the present disclosure;

FIGS. 3 to 6 illustrate structural schematic diagrams of multiple variations of a protruding structure of the TOF optical sensing module according to an embodiment of the present disclosure.

### DETAILED DESCRIPTION

For a better understanding of the technical features of the present disclosure, a clear and complete description of the embodiments of the present disclosure will be set forth with reference to the drawings. Obviously, the described embodiments are only a part, rather than all, of the embodiments of the present disclosure. All other embodiments derived by persons skilled in the art from the embodiments of the present disclosure without making inventive efforts shall fall within the scope of the present disclosure.

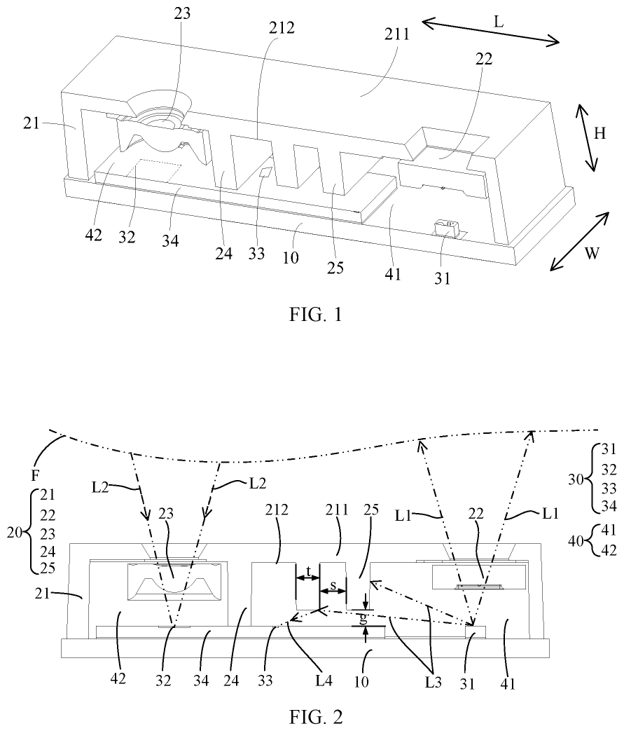

FIGS. 1 and 2 illustrate structural schematic diagrams of a TOF optical sensing module according to an embodiment of the present disclosure. As illustrated in FIGS. 1 and 2, a TOF optical sensing module according to an embodiment of the present disclosure includes a substrate 10, a cap 20, and a transceiving unit 30.

The substrate 10 may include one or more insulating layers and electroconductive layers, such as a printed circuit board or a ceramic substrate.

As illustrated in FIGS. 1 and 2, the cap 20 includes an opaque body 21, and a transmitting window 22, a receiving window 23, a partition structure 24 and at least one protruding structure 25 all connected to the body 21. The body 21 and the substrate 10 together define a chamber 40. Illustratively, the body 21 of substantially inverse U-shaped covers the substrate 10 to form the chamber 40. The body 21 has a top wall 211 with a lower surface 212, and the lower surface 212 faces the substrate 10 and the chamber 40. It can be understood that the lower surface 212 is in the chamber 40 and opposite to the substrate 10. The protruding structure 25 protrudes from the lower surface 212 toward the chamber 40, i.e., the protruding structure 25 protrudes from the lower surface 212 toward the substrate 10.

As illustrated in FIGS. 1 and 2, the transceiving unit 30 is disposed in the chamber 40, and for example, may be disposed on the substrate 10. The partition structure 24 is disposed between the lower surface 212 and the substrate 10 to divide the chamber 40 into an emitting chamber 41 and a receiving chamber 42 respectively corresponding to the transmitting window 22 and the receiving window 23, in conjunction with the transceiving unit 30. It can be understood that the partition structure 24 is disposed between the transmitting window 22 and the receiving window 23. The partition structure 24 may be fixed to the lower surface 212 of the body 21. Optionally, the partition structure 24 and the body 21 are of an integrated structure or a split structure. The partition structure 24 may divide the chamber 40 into the emitting chamber 41 and the receiving chamber 42 which are partially communicated or completely uncommunicated with each other, in conjunction with the transceiving unit 30. Each of the protruding structures 25 is disposed in the emitting chamber 41, i.e., each of the protruding structures 25 is disposed between the partition structure 24 and the transmitting window 22. Optionally, the protruding structure 25 and the body 21 are of an integrated structure or a split structure.

As illustrated in FIGS. 1 and 2, the transceiving unit 30 is configured to emit detection light L1 from the emitting chamber 41. Since the emitted detection light L1 has a predetermined divergence angle, a portion of the detection light L1 travels through the transmitting window 22, irradiates a target object F above the cap 20, then is reflected from the object F, and then travels through the receiving window 23 and is received in the receiving chamber 42 by the transceiving unit 30 as sensing light L2. Another portion of the detection light L1 (hereinafter referred to as stray light L3) does not travel through the transmitting window 22, and is reflected in the emitting chamber 41. In the embodiment, by disposing the protruding structure 25 in the emitting chamber 41, the reflection and/or absorption of the stray light L3 by the emitting chamber 41 can be increased, thus reducing or preventing the stray light L3 from entering the receiving chamber 42. Specifically, the protruding structure 25 increases the inner surface area of the emitting chamber 41, thus increasing the reflection and absorption amount and/or reflection and absorption times of the stray light L3, so as to attenuate energy of the stray light. Therefore, as compared with the traditional TOF optical sensing module, the TOF optical sensing module according to the embodiment of the present disclosure can reduce or completely prevent the stray light from entering the receiving chamber 42, thus improving the accuracy of measuring the distance of the object F.

As an optional technical solution, the partition structure 24, in conjunction with the transceiving unit 30, divides the chamber 40 into the emitting chamber 41 and the receiving chamber 42 which are partially communicated with each other. In this solution, although there is a gap between the partition structure 24 and the transceiving unit 30, the protruding structure 25 can reduce or prevent the stray light from entering the receiving chamber 42 through the gap, thus improving the accuracy of measuring the distance of the object F.

As another optional technical solution, the partition structure 24, in conjunction with the transceiving unit 30, divides the chamber 40 into the emitting chamber 41 and the receiving chamber 42 which are completely uncommunicated with each other, so as to prevent the mutual interference between the receiving chamber 42 and the emitting chamber 41. In this solution, since there is no gap between the partition structure 24 and the transceiving unit 30, the stray light can be prevented from entering the receiving chamber 42 through the gap, while the protruding structure 25 can reduce or prevent the stray light from entering the receiving chamber 42 through the partition structure 24, thus further improving the accuracy of measuring the distance of the object F.

In some embodiments, as illustrated in FIG. 1, the chamber 40 defines a length direction L, a width direction W and a height direction H which are perpendicular to each other. The partition structure 24 divides the chamber 40 into the emitting chamber 41 and the receiving chamber 42 in the length direction L. The protruding structures 25 are distributed in at least part of a length range between the transmitting window 22 and the partition structure 24 in the length direction L. In other words, the protruding structures 25 are distributed in the whole or part of the length range between the transmitting window 22 and the partition structure 24. Each of the protruding structures 25 extends in at least part of a width range of the chamber 40 in the width direction W. In other words, each of the protruding structures 25 extends in the whole or part of the width range of the chamber 40. In the case where the protruding structures 25 extends in the whole width range of the chamber 40, the size of the protruding structure 25 in the width direction W is equal to the width of the chamber 40. A gap is provided between each of the protruding structures 25 and the transceiving unit 30 in the height direction H. In other words, each of the protruding structures 25 does not contact the upper surface of the transceiving unit 30.

In some embodiments, as illustrated in FIGS. 1 to 4, the cap 20 includes at least two protruding structures 25, which are arranged at an interval in the length direction L, so as to further increase the inner surface area of the chamber 40, particularly the inner surface area of the emitting chamber 41, and increase the reflection and absorption amount and/or reflection and absorption times of the stray light L3, thus further improving the accuracy of measuring the distance of the object F.

In the embodiments, as illustrated in FIG. 2, optionally, a thickness t of each of the protruding structures 25 in the length direction L is not less than 0.1 mm. The greater the thickness t of the protruding structure 25, the greater the surface area of the protruding structure 25 and the greater the mount of the stray light L3 reflected and absorbed by the protruding structure 25. Optionally, the thicknesses t of the protruding structures 25 may be the same or different.

In the embodiments, as illustrated in FIG. 2, optionally, a spacing s between two adjacent protruding structures 25 in the length direction L is not less than 0.1 mm. The spacing s provides a transmission space for the stray light L3. If the spacing s is too small, it is not conducive to the transmission of the stray light L3, resulting in the reduction of the reflection times of the stray light L3. If the spacing s is too large, it is impossible to dispose a large number of protruding structures 25 in a limited space. Therefore, in the actual design, appropriate thickness t and spacing s can be reasonably determined within the above value ranges according to the specific size of the emitting chamber 41. Optionally, the spacing s between any two adjacent protruding structures 25 may be the same or different.

In the embodiments, as illustrated in FIG. 2, optionally, a gap g between each of the protruding structures 25 and the transceiving unit 30 is not more than 1 mm. The smaller the gap g, the more effective the protruding structures 25 is in preventing the stray light L3. Thus, the gap g should be determined as small as possible under the condition that the protruding structures 25 do not affect the wire bonding on the chip of the transceiving unit 30 in the packaging process. Optionally, the gaps g between the protruding structures and the transceiving unit 30 may be the same or different.

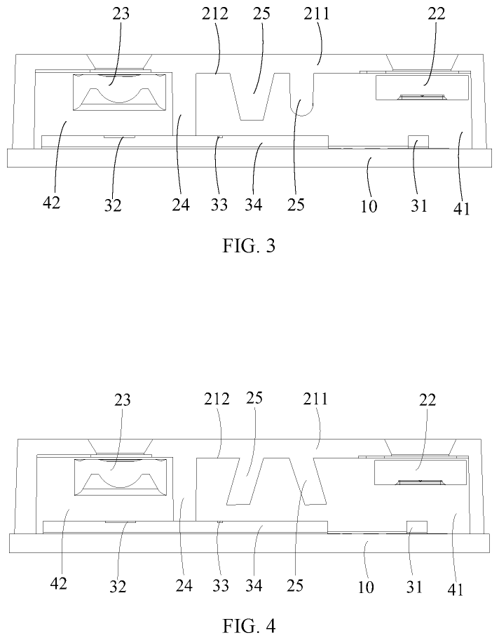

In the embodiments, as illustrated in FIGS. 3 and 4, the shapes of the protruding structures 25 may be the same or different. The shape of a single protruding structure 25 may be regular or irregular. Illustratively, the longitudinal section of the protruding structure 25 may be in the shape of a rectangle (as illustrated in FIG. 2), a triangle, an inverted trapezoid (as illustrated in FIG. 3), a regular trapezoid, a parallelogram (as illustrated in FIG. 4), a rectangle at the upper part and a semicircle or ellipse at the lower part (as illustrated in FIG. 3), a wavy, or a step. Each of the protruding structures 25 may extend along a vertical direction, or an inclined direction which is inclined relative to the vertical direction. In the case where the protruding structures 25 extent in the inclined direction, the inclined directions and the inclined angles of the protruding structures 25 may be the same or different. For example, as illustrated in FIG. 4, at least one protruding structure 25 is inclined in a direction gradually approaching the partition structure 24 from top to bottom, i.e., a direction gradually away from a light-emitting unit 31 from top to bottom; and at least one other protruding structure 25 is inclined in a direction gradually away from the partition structure 24 from top to bottom, i.e., a direction gradually approaching the light-emitting unit 31 from top to bottom. The light-emitting unit 31 is disposed below the transmitting window 22 and configured to emit the detection light L1, as will be described in detail later.

In the embodiments, a single surface (e.g., a side surface or a bottom surface) of each of the protruding structures 25 may be a smooth surface or an uneven surface, and the latter has a larger surface area, which is more conducive to increasing the reflection and absorption amount and/or the reflection and absorption times of the stray light L3.

Optionally, at least one surface of the at least one protruding structure 25 is provided with a coating layer for absorbing the stray light L3, so as to reduce or prevent the stray light L3 from entering the receiving chamber 42. According to the light wave emitted by the light-emitting unit 31, a material that can easily absorb the light wave (e.g., infrared light) may be selected as the material of the coating layer to increase the absorption rate of the light wave. When the light wave emitted by the light-emitting unit 31 is infrared light, the coating layer may be an infrared light absorption coating layer, and the material of the coating layer may be an organic color material that can absorb the infrared light, such as an infrared light absorber.

Illustratively, at least one surface of each of the protruding structures 25 is provided with the coating layer, or all surfaces of each of the protruding structures 25 exposed in the emitting chamber 41 are provided with the coating layer to improve the absorption amount and/or the absorption times of the stray light L3.

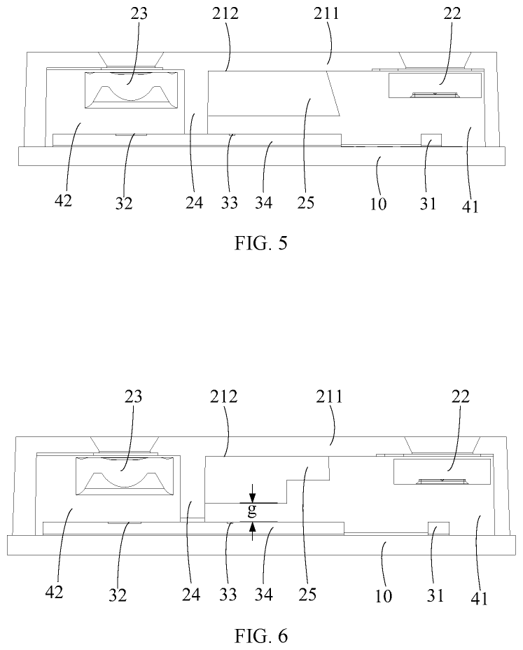

In other embodiments, as illustrated in FIGS. 5 and 6, the cap 20 includes one protruding structure 25, which extends continuously in the length direction L. In the embodiments, since there is one protruding structure 25, it may be configured to have a larger size in the length direction L than any one of the at least two protruding structures 25 in the previous embodiments, so as to achieve the effect of increasing the surface area.

In the embodiments, optionally, the shape of the protruding structure 25 may be regular or irregular. Illustratively, the longitudinal section may be in the shape of a trapezoid (as illustrated in FIG. 5) or a step (as illustrated in FIG. 6), or any other shape listed in the previous embodiments.

In the embodiments, the gap g between various portions of the bottom surface of the protruding structure 25 and the transceiving unit 30 may be different. Optionally, the gap g between a lowest portion of the protruding structure 25 and the transceiving unit 30 is not more than 1 mm, i.e., a minimum gap g between the protruding structure 25 and the transceiving unit 30 is not more than 1 mm.

In the embodiments, optionally, a single surface (e.g., a side surface or a bottom surface) of the protruding structure 25 may be a smooth surface or an uneven surface, and the latter has a larger surface area, which is more conducive to increasing the reflection and absorption amount and/or the reflection and absorption times of the stray light L3.

In some embodiments, each of the protruding structures 25 is spaced apart from the partition structure 24, i.e., the protruding structure 25 is spaced apart from the partition structure 24 in the length direction L.

In other embodiments, at least one protruding structure 25 is in contact with the partition structure 24. When there are two or more protruding structures 25, the side surface of the protruding structure 25 closest to the partition structure 24 may be attached to the partition structure 24. When there is one protruding structure 25, the side surface of the protruding structure 25 facing the partition structure 24 may be attached to the partition structure 24, as illustrated in FIGS. 5 and 6.

In some embodiments, as illustrated in FIG. 2, the transceiving unit 30 includes a light-emitting unit 31, a sensing pixel 32, and a reference pixel 33.

As illustrated in FIG. 2, the reference pixel 33 is disposed in the emitting chamber 41 and between the partition structure 24 and the transmitting window 22 to receive reference light L4.

As illustrated in FIG. 2, the sensing pixel 32 is disposed in the receiving chamber 42 and below the receiving window 23 to receive sensing light L2.

As illustrated in FIG. 2, the light-emitting unit 31 is disposed in the emitting chamber 41 and below the transmitting window 22. The light-emitting unit 31 is configured to emit the detection light L1. A portion of the detection light L1 travels through the transmitting window 22, then irradiates a target object F above the cap 20, then reflected from the object F, and then travels through the receiving window 23 and is received by the sensing pixel 32 as sensing light L2. Another portion of the detection light L1 (i.e., the stray light L3) is reflected and/or absorbed in the emitting chamber 41 by the protruding structure 25, and then is at least partially received by the reference pixel 33 as reference light L4. It can be understood that the reference light L4 received by the reference pixel 33 is significantly less than the stray light L3, which is conductive to reducing the detection light L1 reaching the reference pixel 33, thus avoiding the problem that the energy of the detection light received by the reference pixel of the traditional TOF optical sensing module is too high and additional processing is required to reduce the energy received by the reference pixel.

In some embodiments, at least part of the at least one protruding structure 25 is disposed between the reference pixel 33 and the transmitting window 22. For example, a part of the at least one protruding structure 25 is disposed between the reference pixel 33 and the transmitting window 22, and the other part of the at least one protruding structure 25 is disposed between the partition structure 24 and the reference pixel 33. Alternatively, all of the at least one protruding structure 25 is disposed between the reference pixel 33 and the transmitting window 22 (as illustrated in FIG. 2) to minimize the detection light L1 reaching the reference pixel 33.

In some other embodiments, all of the at least one protruding structure 25 may be disposed between the reference pixel 33 and the partition structure 24.

The ranging principle of the TOF optical sensing module will now be introduced with reference to the structure of the transceiving unit 30 in the embodiments.

The TOF optical sensing module measures the distance of the object based on a mathematical formula of 2 L=CΔt, where L denotes the distance from the optical sensing module to the target object F, C denotes the speed of light, and Δt denotes the traveling time of light (herein defined as the time difference between the emitting time and the receiving time), so it is necessary to determine an emitting time instant and a receiving time instant respectively. The receiving time instant may be determined according to the sensing electrical signal generated by the sensing pixel 32 upon receipt of the sensing light L2, and the emitting time instant may be determined according to the reference electrical signal generated by the reference pixel 33 upon receipt of the detecting light L1 in the emitting chamber 41. As mentioned above, the light-emitting unit 31 has a predetermined divergence angle, so the other portion of the detection light L1 emitted by the light-emitting unit 31 will be reflected in the emitting chamber 41. Since the traveling distance of the other portion of the detection light L1 reflected in the chamber 40 can be neglected when compared with the distance (2 L) of the target object F, the time instant at which the reference pixel 33 receives the other portion of the detection light L1 (i.e., the reference light L4) can be set as the emitting time instant.

In some other embodiments, a time instant at which the light-emitting unit 31 is controlled to emit light may be set as the emitting time instant, or the above time instant plus a predetermined delay time may be set as the emitting time instant.

In some embodiments, the light-emitting unit 31 is configured to emit the radiation (e.g., infrared (IR) light) with a specific frequency or frequency range. The light-emitting unit 31 may be a VCSEL or a Light-Emitting Diode (LED), such as an infrared LED. The light-emitting unit 31 may be attached to the upper surface of the substrate 10 through an adhesive material, and may be electrically connected to the substrate 10 through, for example, bonding wires or electroconductive bumps.

In some embodiments, as illustrated in FIGS. 1 and 2, the transceiving unit 30 includes a pixel substrate 34, which may be fixed on the substrate 10. The partition structure 24, in conjunction with the pixel substrate 34, divides the chamber 40 into the emitting chamber 41 and the receiving chamber 42, i.e., the bottom of the partition structure 24 is tightly attached to an upper surface of the pixel substrate 34. A gap is provided between the protruding structure 25 and the upper surface of the pixel substrate 34, i.e., the bottom of the protruding structure 25 does not contact the upper surface of the pixel substrate 34. The sensing pixel 32 and the reference pixel 33 are formed in the pixel substrate 34.

A portion of the pixels is a photosensitive structure, such as a photodiode, an Avalanche Photo Diode (APD) and the like, which is the SPAD in this embodiment. The other portion of the pixels is a sensing circuit for processing an electrical signal coming from the photosensitive structure. The material of the pixel substrate 34 may include a semiconductor material, such as silicon, germanium, gallium nitride, silicon carbide, gallium arsenide, gallium phosphide, indium phosphide, indium arsenide, indium antimonide, silicon germanium alloy, gallium arsenide phosphide alloy, aluminum indium arsenic alloy, aluminum gallium arsenic alloy, gallium indium arsenic alloy, gallium indium phosphide alloy, gallium indium arsenic phosphide alloy or combinations thereof. The pixel substrate 34 may further include one or more electric elements (e.g., integrated circuits). The integrated circuit may be an analog or digital circuit, which may be realized as an active element, a passive element, an electroconductive layer, a dielectric layer and the like formed in a chip and achieve an electrical connection according to the electric design and the function of the chip. The pixel substrate 34 may be electrically connected to the substrate 10 through bonding wires or electroconductive bumps, and then electrically connected to an external device and the light-emitting unit 31, whereby the operations of the light-emitting unit 31, the sensing pixel 32 and the reference pixel 33 can be controlled by the chip, and a function of signal processing can be provided by the chip.

In some embodiments, the chamber 40 may be a solid body made of a light-transmission molding compound, and the body 21 may be made of an opaque material such as an opaque molding compound, metal and the like, and covers the chamber 40 made of the light-transmission molding compound with a portion of the light-transmission molding compound corresponding to the receiving window 23 and the transmitting window 22 being exposed.

In other embodiments, the chamber 40 may be filled with air with a pressure higher than or lower than one atmosphere. It can be understood that the cap 20 of this embodiment may be previously formed and adhered to the substrate 10. For example, the cap 20 may be directly and partially or entirely formed on the substrate 10 by way of injection molding. The receiving window 23 and the transmitting window 22 may be hollow openings penetrating the top wall 211 of the body 21, or may be optical devices with special optical functions such as optical filters of specific wavelengths, lenses or diffractive elements with the light defocusing or focusing function, and the like, or may be combinations of elements with multiple optical functions, such as the former two elements. For example, the transmitting window 22 is a scattering lens to increase an irradiation range of the detection light L1 for the target object F, and the receiving window 23 is a condensing lens to focus the sensing light L2 on the sensing pixel 32.

The disclosure has been described above with reference to the specific embodiments, but it should be clear to those skilled in the art that these descriptions are exemplary and not intended to limit the protection scope of the present disclosure. Variations and modifications can be made to the present disclosure by those skilled in the art in light of the spirit and principle of the present disclosure and should fall within the scope of the present disclosure.

1. A TOF optical sensing module, comprising:
a substrate;
a cap comprising a body, and a transmitting window, a receiving window, a partition structure and at least one protruding structure all connected to the body, wherein the body and the substrate together define a chamber, the body has a lower surface facing the substrate and the chamber, and the at least one protruding structure protrudes from the lower surface toward the chamber; and
a transceiving unit provided in the chamber, wherein the partition structure is disposed between the lower surface and the substrate to divide the chamber into an emitting chamber and a receiving chamber respectively corresponding to the transmitting window and the receiving window, in conjunction with the transceiving unit; the transceiving unit is configured to emit detection light from the emitting chamber and receive sensing light in the receiving chamber through the receiving window; and each of the at least one protruding structure is disposed in the emitting chamber to reflect and/or absorb the detection light traveling in the emitting chamber towards the receiving chamber.

2. The TOF optical sensing module according to claim 1, wherein:
the chamber defines a length direction, a height direction and a width direction, and the partition structure divides the chamber into the emitting chamber and the receiving chamber in the length direction;
the at least one protruding structure is distributed in at least part of a length range between the transmitting window and the partition structure in the length direction;
each of the at least one protruding structure extends in at least part of a width range of the chamber in the width direction; and
a gap is provided between each of the at least one protruding structure and the transceiving unit in the height direction.

3. The TOF optical sensing module according to claim 2, wherein:
the cap comprises at least two protruding structures, which are arranged at an interval in the length direction.

4. The TOF optical sensing module according to claim 3, wherein:
a thickness of each of the at least two protruding structures in the length direction is not less than 0.1 mm; and/or,
the interval between two adjacent protruding structures in the length direction is not less than 0.1 mm; and/or,
the gap between each of the at least two protruding structures and the transceiving unit is not more than 1 mm.

5. The TOF optical sensing module according to claim 2, wherein:
the cap comprises one protruding structure, which extends continuously in the length direction.

6. The TOF optical sensing module according to claim 5, wherein:
a minimum gap between the protruding structure and the transceiving unit is not more than 1 mm.

7. The TOF optical sensing module according to claim 1, wherein:
each of the at least one protruding structure is spaced apart from the partition structure; or
at least one of the at least one protruding structure is in contact with the partition structure.

8. The TOF optical sensing module according to claim 1, wherein:
the transceiving unit comprises at least one reference pixel, and at least part of the at least one protruding structure is disposed between the reference pixel and the transmitting window.

9. The TOF optical sensing module according to claim 8, wherein:
all of the at least one protruding structure is disposed between the reference pixel and the transmitting window.

10. The TOF optical sensing module according to claim 1, wherein the transceiving unit comprises:
a reference pixel disposed in the emitting chamber and between the partition structure and the transmitting window;
a sensing pixel disposed in the receiving chamber and below the receiving window; and
a light-emitting unit disposed in the emitting chamber and below the transmitting window for emitting the detection light, wherein a portion of the detection light travels through the transmitting window, irradiates a target object above the cap, then is reflected from the target object, and then travels through the receiving window and is received by the sensing pixel as sensing light; and another portion of the detection light is reflected and/or absorbed in the emitting chamber by the at least one protruding structure, and then is at least partially received by the reference pixel as reference light.

11. The TOF optical sensing module according to claim 1, wherein:
the emitting chamber and the receiving chamber are not communicated with each other.

12. The TOF optical sensing module according to claim 1, wherein:
at least one surface of the at least one protruding structure is provided with a coating layer for absorbing the detection light.
